(19) United States
(12) Patent Application Publication
(10) Pub. No.: US 2025/0275417 A1
(43) Pub. Date: Aug. 28, 2025

(54) Display Device

(71) Applicant: LG Display Co., Ltd., Seoul (KR)

(72) Inventor: Jin Young Kim, Paju-si (KR)

(21) Appl. No.: 18/820,879

(22) Filed: Aug. 30, 2024

(30) Foreign Application Priority Data
Feb. 23, 2024 (KR) 10-2024-0026302

(51) Int. Cl. H10K 59/80; H10K 59/40; H10K 102/00

(52) U.S. Cl. CPC H10K 59/872; H10K 59/40; H10K 59/8722; H10K 59/873; H10K 2102/311

(57) ABSTRACT

A display device presented herein includes a display panel; a cover on a front surface of the display panel; an adhesive member in a groove, the groove is in a concave form on a front surface of the cover and has a ring shape; and a knob coupled to the groove through the adhesive member.

### CROSS-REFERENCE TO RELATED APPLICATION

This application claims the priority of Republic of Korea Patent Application No. 10-2024-0026302, filed on Feb. 23, 2024, which is hereby incorporated by reference in its entirety.

### BACKGROUND

### Field

The present disclosure relates to a display device.

### Description of Related Art

Display devices may include organic light-emitting display devices, in which organic light-emitting diodes (OLED) are arranged, inorganic light-emitting displays devices, in which inorganic light-emitting diodes (LED) are arranged and liquid crystal display devices.

For example, the display device displays an image using self-light-emitting elements, and thus may be realized in various thin shapes without requiring a separate light source, for example, a backlight unit.

### SUMMARY

The present disclosure provides a display device that supports a knob while guiding the knob to a preset position using a ring-shaped groove formed in a cover covering a display panel.

The present disclosure provides a display device including a structurally improved cover and knob for use in both flat and curved display devices.

Objectives to be solved by embodiments of the present disclosure are not limited to the objectives described above, and objectives which are not described above will be clearly understood by those skilled in the art from the following descriptions.

The display device according to one or more embodiments of the present disclosure includes a display panel; a cover on a front surface of the display panel; an adhesive member in a groove, the grove is in a concave form on a front surface of the cover and has a ring shape; and a knob coupled to the groove through the adhesive member.

Embodiments of the present disclosure may prevent the knob from falling out while positioning the knob at a preset position by using the ring-shaped groove formed on the surface of the cover and the knob coupled to the groove.

Embodiments of the present disclosure may provide a coupling structure of the ring-shaped groove formed in the cover and the knob coupled to the groove for use in both flat panel type and curved display devices. Accordingly, embodiments of the present disclosure enable low power operation of the manufacturing process in terms of reducing manufacturing energy by commonizing the knob.

Embodiments of the present disclosure may be used in a curved display device having at least two curvatures by structurally improving the groove and the knob corresponding to the groove.

Various useful advantages and effects of the embodiments of the present disclosure are not limited to the above-described contents, and effects which are not described above will be clearly understood by those skilled in the art from the following descriptions.

### BRIEF DESCRIPTION OF THE DRAWINGS

The above and other objects, features, and advantages of the present disclosure will become more apparent to those of ordinary skill in the art by describing embodiments thereof in detail with reference to the attached drawings, in which:

FIG. 1 is a perspective view illustrating a display device according to one or more embodiments of the present disclosure;

FIG. 2 is an exploded perspective view illustrating a display device according to one or more embodiments of the present disclosure;

FIG. 3 is a bottom perspective view illustrating a display device according to one or more embodiments of the present disclosure;

FIG. 4 is a cross-sectional view showing an arrangement relationship between a display panel, a cover, and a knob of a display device according to one or more embodiments of the present disclosure;

FIG. 5 is a block diagram schematically illustrating a configuration of a display device according to one or more embodiments of the present disclosure;

FIG. 6 is a diagram schematically illustrating a cross-sectional structure of a display panel disposed in a display device according to one or more embodiments of the present disclosure;

FIG. 7 is a diagram schematically illustrating a cross-sectional structure of a groove of a cover disposed in a display device according to one or more embodiments of the present disclosure;

FIG. 8 is a diagram illustrating an image implemented in an area A of FIG. 1 according to one or more embodiments of the present disclosure;

FIG. 9 is a perspective view illustrating a knob disposed on a display device according to one or more embodiments of the present disclosure;

FIG. 10 is a cross-sectional view illustrating a knob disposed in a display device according to one or more embodiments of the present disclosure;

FIG. 11 is a view showing a coupling relationship between a key groove of a cover and a key of a knob disposed in a display device according to one or more embodiments of the present disclosure;

FIG. 12 is a view showing an example of a centering rib of a knob disposed in a display device according to one or more embodiments of the present disclosure;

FIG. 13 is a view showing another example of the centering rib of the knob disposed in the display device according to one or more embodiments of the present disclosure;

FIG. 14 is a perspective view illustrating a display device according to one or more embodiments of the present disclosure;

FIG. 15 is a cross-sectional view illustrating a display device according to one or more embodiments of the present disclosure;

FIG. 16 is a cross-sectional view illustrating a display device according to one or more embodiments of the present disclosure;

FIG. 17 is a perspective view illustrating a display device according to one or more embodiments of the present disclosure;

FIG. 18 is a cross-sectional view illustrating a display device according to one or more embodiments of the present disclosure;

FIG. 19 is a cross-sectional view illustrating a display device according to one or more embodiments of the present disclosure;

FIG. 20 is a perspective view illustrating a display device according to one or more embodiments of the present disclosure;

FIG. 21 is a diagram illustrating a cover having at least two curvatures in a display device according to one or more embodiments of the present disclosure;

FIG. 22 is a cross-sectional view illustrating a display device according to one or more embodiments of the present disclosure;

FIG. 23 is a cross-sectional view illustrating a display device according to one or more embodiments of the present disclosure;

FIG. 24 is a perspective view illustrating a display device according to one or more embodiments of the present disclosure;

FIG. 25 is a diagram illustrating a cover having at least two curvatures in a display device according to one or more embodiments of the present disclosure;

FIG. 26 is a cross-sectional view illustrating a display device according to one or more embodiments of the present disclosure;

FIG. 27 is a cross-sectional view illustrating a display device according to one or more embodiments of the present disclosure; and

FIG. 28 is a view illustrating an example of use of a display device, wherein the display device is provided in the vehicle according to one or more embodiments of the present disclosure.

### DETAILED DESCRIPTION

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure. The present disclosure is only defined within the scope of the accompanying claims.

In describing the present disclosure, detailed descriptions of known related technologies may be omitted so as not to unnecessarily obscure the subject matter of the present disclosure.

The terms such as “comprising”, “including”, “having” and “consisting of” used herein are generally intended to allow other components to be added unless the terms are used with the term “only”. References to the singular shall be construed to include the plural unless expressly stated otherwise.

When describing a positional or interconnected relationship between two components, such as “on top of”, “above”, “below”, “next to”, “connect or couple with”, “crossing”, “intersecting” etc., one or more other components may be interposed between them unless “immediately” or “directly” is used.

When describing a temporal contextual relationship, such as “after”, “following”, “next to” or “before”, it may not be continuous on a time scale unless “immediately” or “directly” is used.

The terms “first”, “second” and the like may be used to distinguish components from each other, but the functions or structures of the components are not limited by ordinal numbers or component names in front of the components.

The following embodiments may be combined or associated with each other in whole or in part, and various types of interlocking and driving are technically possible. The embodiments may be implemented independently of each other or together in an interrelated relationship.

Terms used in the embodiments of the disclosure (including technical and scientific terms) are to be construed as they would be commonly understood by one of ordinary skill in the art to which the disclosure belongs, unless otherwise specifically defined and described, and commonly used terms, such as dictionary defined terms, are to be construed in light of their contextual meaning in the relevant art.

Hereinafter, embodiments of the present disclosure will be described in detail with reference to the accompanying drawings.

The display device according to one or more embodiments of the present disclosure may be used in a display device for a vehicle, and a controller such as a knob may be used to operate the display device.

Since these knobs are disposed on the cover on the display panel using an adhesive tape, there is a problem that it is difficult for the knob to be aligned at a preset position. In addition, there is a problem that the knob is removed from the cover covering the display panel by the external force acting on the knob.

Accordingly, the development of a structurally improved display device is required to guide the knob to the preset position while preventing the knob from dropping due to external force.

In the display device according to one or more embodiments of the present disclosure, the knob may be positioned in the preset position by using a ring-shaped groove concavely formed in the cover and the knob coupled to the groove, and at the same time the knob may be prevented from falling out due to an external force. Accordingly, the display device according to one or more embodiments of the present disclosure may improve the life of the display device through durability improvement, thereby enabling greenhouse gas reduction in terms of manufacturing energy reduction.

The display device according to one or more embodiments of the present disclosure may improve the productivity of the display device by providing a coupling structure of the groove and the knob that may be used in both a flat panel display device and a curved display device.

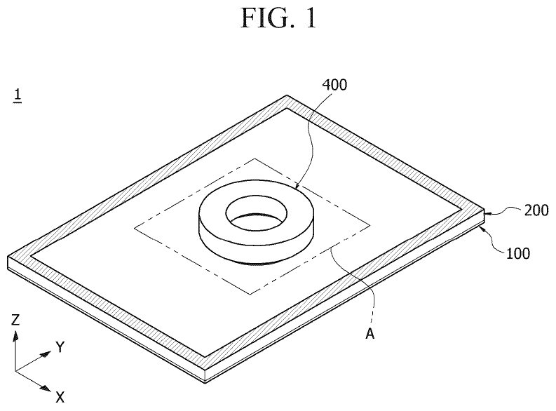

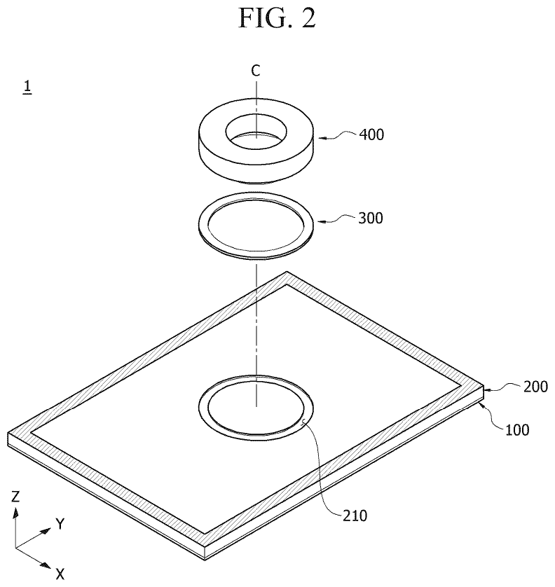

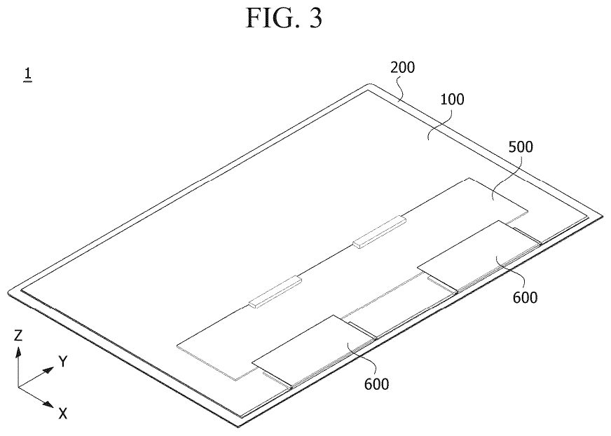

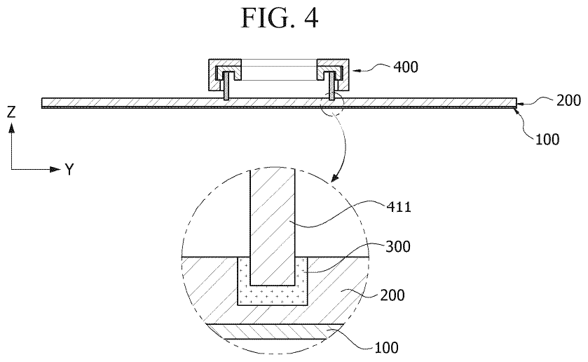

FIG. 1 is a perspective view illustrating a display device according to one or more embodiments of the present disclosure. FIG. 2 is an exploded perspective view illustrating a display device according to one or more embodiments of the present disclosure. FIG. 3 is a bottom perspective view illustrating a display device according to one or more embodiments of the present disclosure. FIG. 4 is a cross-sectional view illustrating an arrangement relationship between a display panel, a cover, and a knob of a display device according to one or more embodiments of the present disclosure. The flat panel display device illustrated in FIGS. 1 and 2 may be referred to as a display device according to a first embodiment of the present disclosure.

Referring to FIGS. 1 to 4, the display device 1 according to one or more embodiments of the present disclosure may include a display panel 100, a cover 200 disposed on the front surface of the display panel 100, an adhesive member 300 disposed in a groove 210 concavely formed in the front surface of the cover 200, and a controller such as a knob 400 coupled to the groove 210 through the adhesive member 300. For example, the groove 210 may have a predetermined depth and may be formed in a ring shape including an opening. For example, one surface on which the input image is displayed with respect to the display panel 100 may be referred to as the front surface of the display panel 100, and a surface opposite to the front surface may be referred to as the rear surface. Also, an X-axis direction illustrated in FIGS. 1 to 3 may refer to a width direction or a horizontal direction, a Y-axis direction may refer to a length direction or a vertical direction, and a Z-axis direction may refer to a up and down direction or a thickness direction. Also, the X-axis direction, the Y-axis direction, and the Z-axis direction may be perpendicular to each other, but may refer to different directions that are not perpendicular to each other. Accordingly, each of the X-axis direction, the Y-axis direction, and the Z-axis direction may be described as one of a first direction, a second direction, and a third direction. And, a surface extending in the X-axis direction and the Y-axis direction may mean a horizontal surface.

In addition, the display device 1 according to one or more embodiments of the present disclosure may include a substrate 500 disposed on the rear surface of the display panel 100, and at least one flexible film 600 connecting the display panel 100 and the substrate 500.

The display panel 100 may display an input image. In addition, the display panel 100 may be formed in a plate shape having a predetermined thickness, and may include a front surface on which an image is implemented and a rear surface opposite to the front surface.

Also, the display panel 100 may include a pad part to which the flexible film 600 is electrically connected. Accordingly, one side of the flexible film 600 may be bonded to the pad part of the display panel 100 through an anisotropic conductive film (ACF).

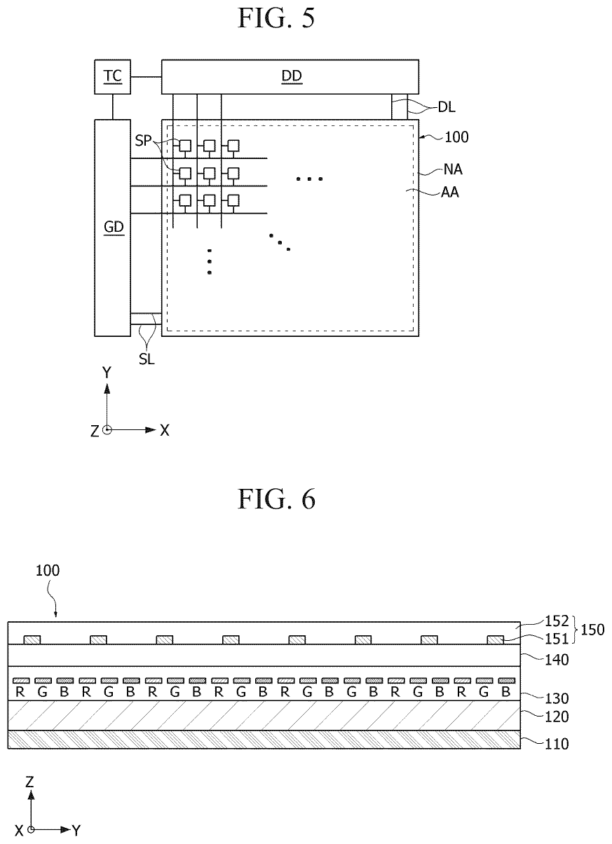

FIG. 5 is a block diagram schematically illustrating a configuration of the display device 1 according to one or more embodiments of the present disclosure.

With reference to FIG. 5, the display device 1 includes a display panel in which a plurality of pixels are arranged in a display area AA and a driving circuit for driving the pixels.

The display panel 100 may be a panel having a rectangular structure with a width in the X-axis direction, a length in the Y-axis direction, and a thickness in the Z-axis direction. The pixels each have a plurality of different sub-pixels SP. The driving circuit includes a data driver DD, a gate driver GD, and a timing controller TC controlling the gate driver GD and the data driver DD. The display area AA, on which an input image is displayed, of the display panel 100 may be a screen that appears when viewed from above the front surface of the display panel 100. In this case, the width and length of the display panel 100 may be set to various design values that vary among application fields of the display device 1.

An input image is displayed on the sub-pixels SPs that are arranged on the display area AA of the display panel 100. For example, the sub-pixels SPs each include a light-emitting element and a pixel circuit that drives the light-emitting element. The light-emitting element may be an organic light-emitting diodes (OLED), a light-emitting diode (LED) or a micro-light-emitting diode (micro-LED).

A plurality of scan lines SL and a plurality of data lines DL are arranged in an intersecting manner on the display panel 100. The sub-pixels SP each are connected to the scan line SL and the data line DL. Power lines, omitted from FIG. 5, may be connected to the sub-pixels SP, respectively. The non-display area NA may be arranged outward from the display area AA of the display panel 100.

The gate driver GD supplies a scan signal to the scan lines SL in response to a gate control signal provided from the timing controller TC. The gate driver GD, as illustrated in FIG. 5, may be arranged in the non-display area NA of the display panel 100 or the gate driver GD may be arranged in the display area AA of the display panel 100.

In response to a data control signal provided from the timing controller TC, the data driver DD converts image data, received from the timing controller TC, into a reference compensation voltage, and outputs a data voltage. The data voltage, output from the data driver DD, is supplied to the data lines DL.

The timing controller TC aligns image data, input from the outside, and supplies the aligned image data to the data driver DD. The timing controller TC may generate the gate control signal and the data control signal based on timing signals, synchronized to an input image signal, for example, based on a dot clock signal, a data enable signal, and a horizontal/vertical synchronization signal. The timing controller TC supplies the gate control signal to the gate driver GD, supplies the data control signal to the data driver DD, and thus controls operational timing of both the gate driver GD and the data driver DD.

A link line and a pad electrode, both for transferring a signal to the sub-pixel SP in the display area AA, may be arranged in the non-display area NA. In addition, one or both of gate and data driver ICs may be arranged in the non-display area NA. The gate driver IC is formed by integrating circuits of the gate driver GD, and the data driver IC is formed by integrating circuits of the data driver DD.

Drivers, such as the gate driver GD, the data driver DD, and the timing controller TC, may be connected to the display panel 100 in various techniques. For example, the gate driver GD may also be arranged in the non-display area NA in a gate-in-panel (GIP) technique, and may also be arranged between the sub-pixels SPs in the display area AA in a gate-in-active-area (GIA) technique. For example, the data driver DD and the timing controller TC are formed on a separate flexible film and a separate printed circuit board (PCB), respectively. Then, the flexible film and the PCB are bonded to a pad electrode formed in the non-display area NA of the display panel 100. Thus, the data driver DD and the timing controller TC may be electrically connected to the display panel 100.

FIG. 6 is a cross-sectional view schematically illustrating a cross-sectional structure of the display area AA of the display device 1 according to one or more embodiments of the present disclosure.

With reference to FIG. 6, the display panel 100 may include a circuit layer 120, arranged on a panel substrate 110, and a light-emitting element layer 130, arranged on the circuit layer 120. In addition, the display panel 100 includes an encapsulation layer 140, arranged on the light-emitting element layer 130, and a touch sensor layer 150, formed on the encapsulation layer 140.

The panel substrate 110 may be formed of an insulation material or of a material with flexibility properties. For example, the panel substrate 110 may be formed of glass, metal, plastic, or the like.

The circuit layer 120 may include a pixel circuit, connected to wires such as data lines, gate lines, and electric power lines, a gate driver, connected to the gate lines, and the like. Wires and circuit elements on the circuit layer 120 may include a plurality of insulation layers, two or more metal layers, separated from each other with the insulation layer in between, and an active layer containing a semiconductor material.

The light-emitting element layer 130 may include a light-emitting element that is driven by the pixel circuit. The light-emitting elements may include a red-color light-emitting element, a green-color light-emitting element, and a blue-color light-emitting element. In another practical example, the light-emitting element layer 130 may include a white-color light-emitting element and a color filter. Light-emitting elements on the light-emitting element layer 130 may be covered by a protective layer including an organic film and a protective film.

The encapsulation layer 140 covers the light-emitting element layer 130 in such a manner as to hermetically seal the circuit layer 120 and the light-emitting element layer 130. For example, the encapsulation layer 140 may have a multi-insulation film structure in which an organic film and an inorganic film are alternately stacked on top of each other. The inorganic film here blocks penetration of moisture or oxygen. The organic film flattens a surface of the inorganic film. When an organic film and an inorganic film are alternately stacked on top of each other, thereby forming several layers, a path for moisture or oxygen to move is lengthened compared to a single layer. This lengthening may effectively block penetration of moisture or oxygen affecting the light-emitting element layer 130.

The touch sensor layer 150 may include capacitive touch sensors 151 that sense touch input based on changes in capacitance before and after the touch input. The touch sensor layer 150 may include metal line patterns that form capacitances of touch sensors 151 and insulating film 152. The insulating film 152 may insulate intersecting portions of the metal line patterns and may flatten a surface of the touch sensor layer 150.

The insulating film 152 may be formed in a single layer structure or a multilayer structure in which an organic film and an inorganic film are stacked in several layers.

The insulating film 152 may be formed as a single layer of an organic material. When the groove 210 is formed on the front surface of the cover 200 through the etching process, the insulating film 152 made of an organic material may serve as an etch stopper. For example, even if the hole through which the etchant penetrates the cover 200 is formed in the etching process of forming the groove 210, the insulating film 152 made of an organic material may prevent the touch sensors 151, the circuit layer 120, the light-emitting element layer 130 and the like from being damaged by the etchant.

In addition, the insulating film 152 may be formed in a multilayer structure in which an organic film and an inorganic film are stacked in several layers, and the organic film of the insulating film 152 may serve as an etch stopper to prevent or at least reduce damage to the touch sensors 151, the circuit layer 120, the light-emitting element layer 130, and the like. In this case, it is preferable that the organic film is disposed on the uppermost layer of the insulating film 152 in contact with the cover 200.

A plate may be further disposed on the rear surface of the display panel 100.

The plate may be attached to a rear surface of the display panel 100 to support and protect the display panel 100. Here, the plate may be made of a material having rigidity and high thermal conductivity, for example, a metal material such as aluminum (Al), copper (Cu), zinc (Zn), silver (Ag), gold (Au), iron (Fe), steel use stainless (SUS), or invar. Accordingly, the plate may dissipate heat generated from the display panel 100 to minimize or at least reduce the temperature difference for each area of the display panel 100, and may uniformly implement the temperature distribution of the display panel 100.

The substrate 500 may be disposed on the rear surface of the display panel 100. If a plate is disposed on the rear surface of the display panel 100, the substrate 500 may be disposed on the rear surface of the plate.

The substrate 500 may include a plate-shaped circuit board body, and circuit elements mounted on the circuit board body. For example, the substrate 500 may include a camera, a main control module of a vehicle, a device for communication, a device for driving the display panel 100, and the like. Also, the substrate 500 may include an internal circuit, and other various active and passive devices. Further, the flexible film 600 may be electrically connected to one side of the circuit board body. Here, the substrate 500 may be a printed circuit board (PCB).

The at least one flexible film 600 may electrically connect the display panel 100 to the substrate 500. In detail, the flexible film 600 may connect the pad electrodes of the display panel 100 to the output terminals of the substrate 500. In this case, the flexible film 600 may be bonded to the display panel 100 through an anisotropic conductive film (ACF). Here, the flexible film 600, but is not limited thereto, may be a flexible printed circuit board (FPCB), and may be a chip-on film (COF) on which an IC having circuits of the data driver DD and/or the gate driver GD integrated therein is mounted. And, the flexible film 600 may be referred to as a flexible circuit film.

The cover 200 may be disposed on the front surface of the display panel 100 to protect the display panel 100. In this case, the cover 200 may be attached to the front surface of the display panel 100 using an adhesive member. Here, the rear surface of the cover 200 may represent one surface of the cover 200 disposed to face the front surface of the display panel 100, and the front surface of the cover 200 may be a surface opposite to the rear surface of the cover 200.

In addition, the horizontal area of the cover 200 may be formed larger than the horizontal area of the display panel 100.

Additionally, the cover 200 may be formed of a transparent material. Accordingly, light irradiated from the display panel 100 may pass through the cover 200. Here, the cover 200 may be a cover glass made of a glass material.

In addition, the cover 200 may include a light shielding layer such as a black matrix disposed at the edge, and the light shielding layer may prevent components disposed in the non-display area NA from being exposed to the outside. For example, the light shielding layer may be disposed on the rear edge of the cover 200 so that a portion of the flexible film 600 disposed to overlap the non-display area NA is not visible from the outside.

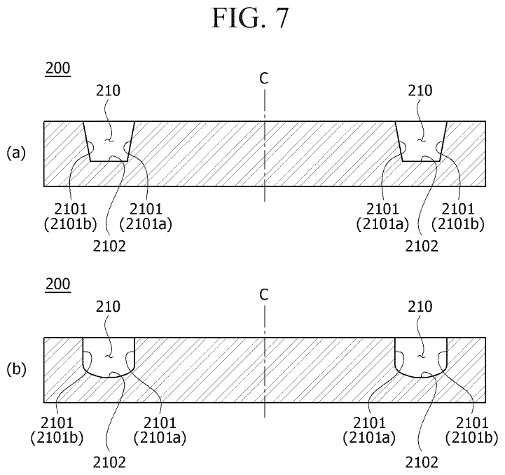

FIG. 7 is a view schematically illustrating a cross-sectional structure of a groove of a cover disposed in a display device according to one or more embodiments of the present disclosure. As illustrated in (a) and (b) of FIG. 7, the groove formed in the cover may be implemented by various embodiments according to a surface processing method.

Referring to FIGS. 2 and 7, the cover 200 may include a ring-shaped groove 210 concavely formed in a front surface of the cover 200. Accordingly, the groove 210 may include two inner side surfaces 2101 disposed to be spaced apart from each other and a bottom surface 2102 connecting the two inner side surfaces 2101. In this case, the inner side surface 2101 may include a first inner side surface 2101a disposed on an inward side and a second inner side surface 2101b disposed on an outward side, and the first inner side surface 2101a and the second inner side surface 2101b may be disposed to be spaced apart from each other. Here, the inward side may refer to a direction toward the center C of the groove 210, and the outward side may refer to an opposite direction of the inward side.

Since the groove 210 is formed in a ring shape, the knob 400 coupled to the groove 210 may be guided to a preset coupling position. For example, since the display device 1 according to the present disclosure includes the ring-shaped groove 210, the knob 400 may be guided to a preset position without using a separate alignment mark and a vision camera.

In addition, since the end of the knob 400 is disposed within the groove 210, even if an external force caused such as by the operation of the knob 400 is applied to the knob 400, the knob 400 may be prevented from falling out by the inner side surface 2101 of the groove 210 supporting the knob 400.

In addition, the groove 210 may be formed by various surface processes performed on the front surface of the cover 200. For example, the groove 210 may be formed through an etching process using an etching solution, a cutting process using a cutting tool such as an end mill, a laser processing process, or the like. In this case, since the cover 200 may be formed of a glass material and the insulating film 152 of the touch sensor layer 150 may be formed of an organic material, the groove 210 of the cover 200 may be formed through an etching process. For example, the cover 200 may be etched by spraying the etching solution onto the cover 200 to which the mask is bonded or by a dipping method of immersing the cover 200 in a water bath containing the etching solution. Accordingly, the inner side surface 2101 of the groove 210 may be formed to have a tapered surface or a rounded edge.

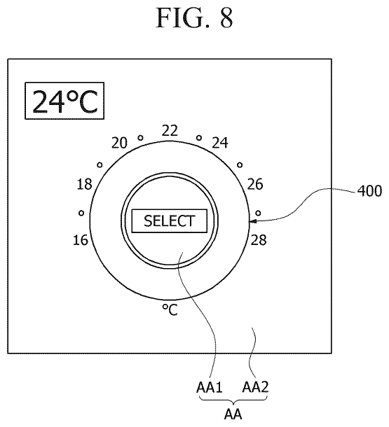

FIG. 8 is a diagram illustrating an image implemented in an area A of FIG. 1 according to one or more embodiments of the present disclosure.

Referring to FIG. 8, an image implemented inside the groove 210 and an image implemented outside the groove 210 may be different from each other with respect to the ring-shaped groove 210. For example, a user of the display device 1 according to one or more embodiments of the present disclosure may control the driving of the display panel 100 using the ring-shaped knob 400, and the display panel 100 may implement images implemented in a first display area AA1 and a second display area AA2 differently with respect to the ring-shaped groove 210. Accordingly, in the display device according to one or more embodiments of the present disclosure, an image implemented inside the knob 400 and an image implemented outside the knob 400 may be implemented differently to enhance user convenience.

The adhesive member 300 may be disposed inside the groove 210 to fix one side of the knob 400. For example, the support part 411 of the knob 400 may be fixed to the cover 200 by an adhesive member 300. In detail, by arranging the adhesive member 300 inside the groove 210 and then arranging the lower end of the support part 411 inside the groove 210, the support part 411 may be fixed to the cover 200. In this case, since the width of the support part 411 is smaller than the width of the groove 210, a space may be formed between the inner side surface 2101 forming the groove 210 and the support part 411.

The adhesive member 300 may be provided as an adhesive tape or a liquid adhesive. For example, a liquid adhesive such as epoxy or resin may be used as the adhesive member 300.

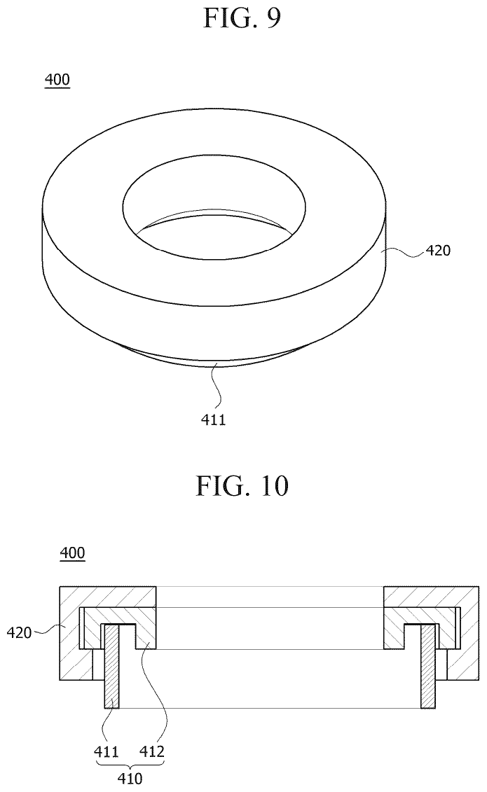

FIG. 9 is a perspective view showing a knob disposed on a display device according to one or more embodiments of the present disclosure, and FIG. 10 is a cross-sectional view showing a knob disposed on a display device according to one or more embodiments of the present disclosure.

Referring to FIGS. 9 and 10, the knob 400 may include a body 410 coupled to the groove 210 and a dial 420 rotatably disposed on the body 410. In addition, the body 410 may include the support part 411 coupled to the groove 210 and a body part 412 disposed on the support part 411.

The support part 411 may be formed in a sleeve shape, a cylindrical shape, or a pipe shape having a predetermined length. In addition, in order to improve a contact area with the liquid adhesive, a lower side surface of the support part 411 may include an inclined surface having a predetermined inclination.

The body part 412 may be formed in a ring shape, and may be detachably disposed on an upper portion of the support part 411. For example, the support part 411 may be detachably coupled to the body part 412 by using a fitting coupling structure, an adhesive member, or a fastening member between the support part 411 and the body part 412. Accordingly, even though the shape of the cover 200 disposed on the flat display device or the curved display device is different, the common use of the body part 412 and the dial 420 may improve the productivity of the display device. Here, in the display device 1 according to one or more embodiments of the present disclosure, an example is that the support part 411 and the body part 412 are detachably coupled, but is not necessarily limited thereto. The support part 411 and the body part 412 may be integrally formed.

The dial 420 may be rotatably disposed on the body 410 and may be formed in a ring shape. Accordingly, an image implemented in the display panel 100 may be visually recognized through the inside of the dial 420. Here, a top surface of the dial 420 may include a plane, and the plane may be parallel to the flat display panel 100.

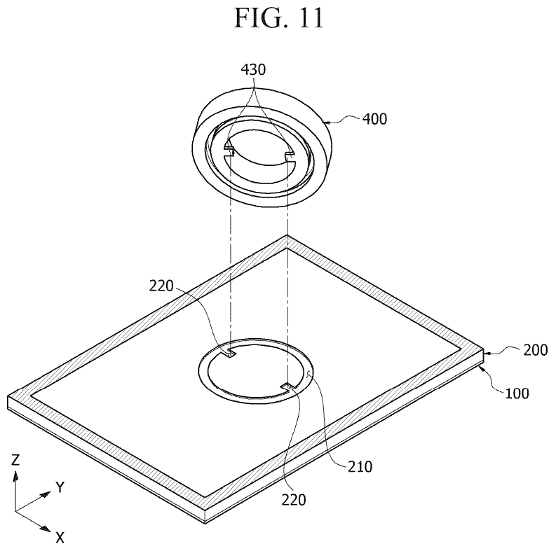

FIG. 11 is a diagram showing a coupling relationship between a key groove of a cover and a key of a knob disposed in a display device according to one or more embodiments of the present disclosure.

Referring to FIG. 11, the cover 200 disposed in the display device 1 according to the embodiment of the present disclosure may further include a key groove 220 extending in a radial direction from the groove 210, and the knob 400 may further include a key 430 protruding from the support part 411 to correspond to the key groove 220.

The key groove 220 may be formed to communicate with the groove 210. Accordingly, the adhesive to be filled in the groove 210 may be filled in the key groove 220 as well.

The key groove 220 may extend in the radial direction from the groove 210 to communicate with the first inner side surface 2101a, but is not necessarily limited thereto. For example, the key groove 220 may extend in the radial direction from the groove 210 to communicate with the second inner side surface 2101b.

The key 430 may be formed to protrude from the inner circumferential surface of the support part 411 in the radial direction, but is not necessarily limited thereto. For example, when the key groove 220 is formed to communicate with the second inner side surface 2101b, the key 430 may be formed to protrude from the outer circumferential surface of the support part 411 in the radial direction. In this case, the key 430 may be formed in a hexahedral shape, but is not necessarily limited thereto.

In addition, the key 430 may be disposed inside the key groove 220 and fixed by the adhesive member 300. Accordingly, the coupling of the key groove 220 and the key 430 may prevent the body 410 from rotating and guide the knob 400 to be coupled at a preset position.

Therefore, the display device 1 according to one or more embodiments of the present disclosure may correspond to a load applied to the knob 400 in the horizontal direction by the coupling of the groove 210 and the support part 411, and may correspond to a load that rotates the body 410 based on the center of the groove 210 through the coupling of the key groove 220 and the key 430.

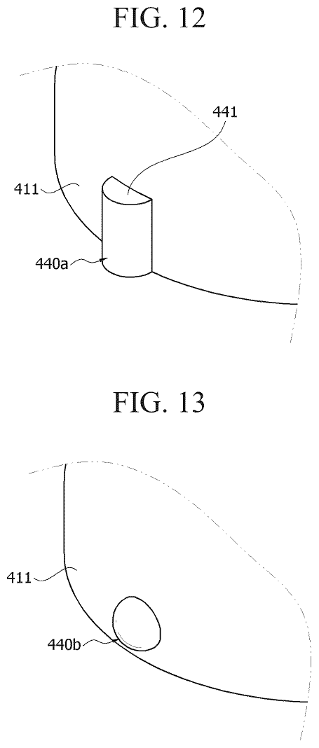

FIG. 12 is a view showing an example of a centering rib of a knob disposed in a display device according to one or more embodiments of the present disclosure, and FIG. 13 is a view showing another example of a centering rib of a knob disposed in a display device according to one or more embodiments of the present disclosure.

Referring to FIGS. 12 and 13, the knob 400 may include at least two centering ribs 440a and 440b formed to protrude from an outer circumferential surface of the support part 411.

The centering ribs 440a and 440b may be formed to protrude from the outer circumferential surface of the support part 411 in a radial direction.

In addition, at least two centering ribs 440a and 440b may be disposed to be spaced apart from each other at a preset interval in the circumferential direction of the support part 411. For example, two or more centering ribs 440a and 440b may be disposed, and when the two centering ribs 440a and 440b are disposed, they may be disposed symmetrically with respect to the center of the support part 411. Here, a center of the support part 411 may be positioned at the same position as a center C of the groove 210. In addition, when the four centering ribs 440a and 440b are disposed, the centering ribs 440a and 440b may be disposed at an interval of 90 degrees in the circumferential direction.

In addition, the centering ribs 440a, 440b are in contact with the second inner side surface 2101b forming the groove 210 to guide the arrangement of the support part 411, allowing the knob 400 to be located at a preset position on the horizontal plane.

In addition, even if the amount of dotting of the adhesive used as the adhesive member 300 is large or small, the centering ribs 440a, 440b may prevent the knob 400 from being tilted to one side.

Furthermore, the centering ribs 440a and 440b may be in line contact or point contact with the second inner side surface 2101b forming the groove 210. That is, since the centering ribs 440a and 440b minimize or at least reduce contact with the second inner side surface 2101b by making a line contact or a point contact with the second inner side surface 2101b, a contact area with the adhesive may be maximized or at least increased. Accordingly, adhesion between the knob 400 and the adhesive may be improved.

As illustrated in FIG. 12, the centering rib 440a may be formed in a semicircular column shape having a predetermined radius. Accordingly, the centering rib 440a may be in line contact with the second inner side surface 2101b. The adhesive may be disposed to cover the upper surface 441 of the centering rib 440a. Accordingly, the adhesion between the knob 400 and the adhesive may be further improved. And, the fixing force of the knob 400 with respect to the cover 200 may be further improved by curing the adhesive.

As shown in FIG. 13, the centering rib 440b may be formed in a hemispherical shape. Accordingly, the centering rib 440b is in point contact with the second inner side surface 2101b forming the groove 210.

The knob 400 of the flat display device 1 described above may be used in a curved display device. Here, the curved display device may include a concave type display device including a concave curved surface and a convex type display device including a convex curved surface.

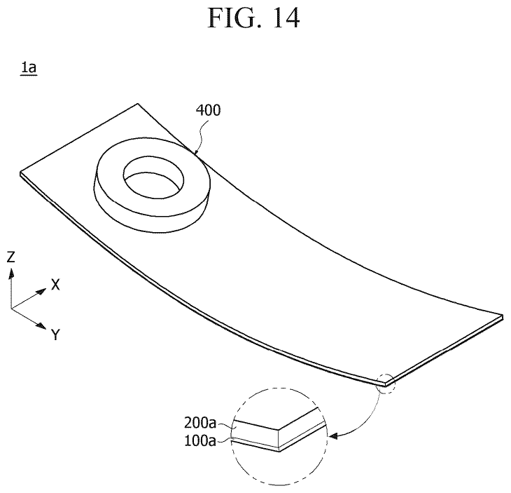

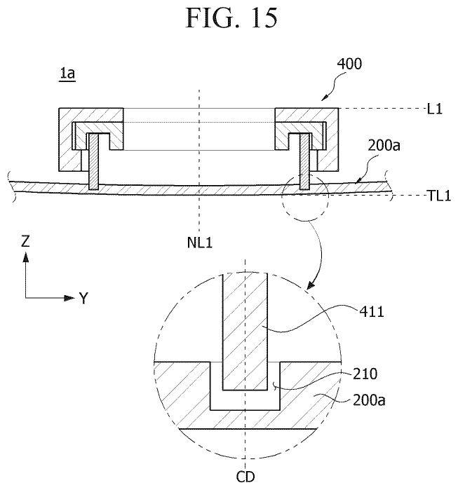

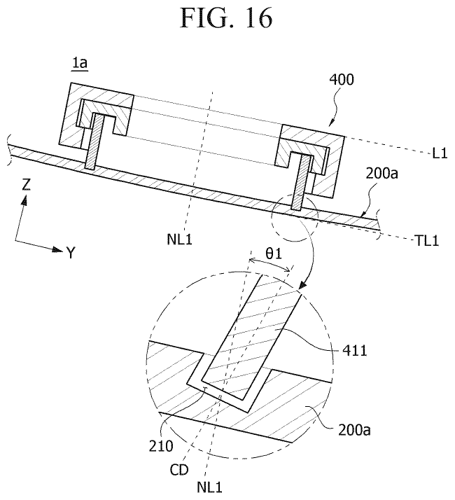

FIG. 14 is a perspective view illustrating a display device according to one or more embodiments of the present disclosure. FIG. 15 is a cross-sectional view illustrating a display device according to one or more embodiments of the present disclosure, which may illustrate an arrangement relationship between the knob and the cover, and the enlarged portion of FIG. 15 may be a conceptual view illustrating technical features of a display device according to another embodiment of the present disclosure. FIG. 16 is a cross-sectional view illustrating a display device according to one or more embodiments of the present disclosure, which may illustrate another arrangement relationship between the knob and the cover, and the enlarged portion of FIG. 16 may be a conceptual view illustrating technical features of a display device according to another embodiment of the present disclosure. Herein, the concave type display device illustrated in FIG. 15 may be referred to as a display device according to a second embodiment of the present disclosure, and the concave type display device illustrated in FIG. 16 may be referred to as a display device according to a third embodiment of the present disclosure.

When comparing the display device 1 according to the first embodiment with the display device 1a according to the second and third embodiments with reference to FIGS. 1 and 14, the cover 200a of the display device 1a according to the second and third embodiments differs from that of the display device 1 according to the first embodiment in that the cover 200a of the display device 1a according to the second and third embodiments includes a concave curved surface.

Also, when comparing the display device 1a according to the second embodiment with the display device 1a according to the third embodiment, the display device 1a according to the second embodiment differs from the display device 1a according to the third embodiment in that the upper surface of the knob 400 in the display device 1a according to the second embodiment is disposed parallel to a tangent line passing through the curved surface of the cover 200a. Here, the tangent line passing through the curved surface of the cover 200a may be a tangent line at the center C of the groove 210.

Referring to FIGS. 14 to 16, a display device 1a according to one or more embodiments of the present disclosure may include a display panel 100a, a cover 200a including a concave curved surface disposed on the front surface of the display panel 100a and formed to have a predetermined curvature, an adhesive member 300 disposed in a groove 210 concavely formed in the front surface of the cover 200a, and a knob 400 coupled to the groove 210 through the adhesive member 300. In this case, the groove 210 may be formed in a ring shape having a predetermined depth. Also, the display device 1a according to one or more embodiments of the present disclosure may include a key groove 220, a key 430 formed to correspond to the key groove 220, centering ribs 440a and 440b, and the like.

The display panel 100a may include a curved surface corresponding to the curved surface of the cover 200a.

The display panel 100a may include a circuit layer 120 disposed on the panel substrate 110, a light-emitting element layer 130 disposed on the circuit layer 120, an encapsulation layer 140 disposed on the light-emitting element layer 130, and a touch sensor layer 150 formed on the encapsulation layer 140.

The cover 200a includes a concave curved surface formed to have a predetermined curvature, and the curved surface may be the front surface of the cover 200a. Accordingly, an imaginary tangent line TL1 contacting the curved surface of the cover 200a may be included.

Depending on the position where the concave type display device 1a is disposed in the vehicle, a difference may occur in the viewing angle of the user viewing the knob 400.

The user's convenience in recognizing the knob 400 may be improved by adjusting the arrangement of the groove 210 in consideration of the position where the concave type display device 1a is disposed.

Referring to FIG. 15, in the display device 1a according to the second embodiment, an imaginary straight line L1 passing through the upper surface of the knob 400 may be disposed in parallel with an imaginary tangent line TL1 contacting the curved surface of the cover 200a. Accordingly, an imaginary normal line NL1 perpendicular to the tangent line TL1 may be perpendicular to an imaginary straight line L1 passing through the upper surface of the knob 400. Here, the upper surface of the knob 400 may be the upper surface of the dial 420.

In this case, the coupling direction CD of the knob 400 of the display device 1a according to the second embodiment may be the same as or parallel to the normal line NL1.

Referring to FIG. 16, in the display device 1a according to the third embodiment, the imaginary straight line L1 passing through the upper surface of the knob 400 may be disposed in non-parallel with the imaginary tangent line TL1 contacting the curved surface of the cover 200a. Accordingly, there is an intersection point at which the imaginary straight line L1 meets the imaginary tangent line TL1. And, a normal line NL1 perpendicular to the tangent line TL1 may be disposed to have a predetermined first inclination angle θ1 with the coupling direction CD in which the support part 411 of the knob 400 is coupled to the groove 210. That is, since the groove 210 of the cover 200a is disposed to be inclined with respect to the normal line NL1, an acute included angle may be formed between the coupling direction CD of the knob 400 and the normal line NL1. As the knob 400 is coupled to the groove 210 formed to be inclined in the front surface of the cover 200a, the position of view in which the knob 400 is recognized may be adjusted, thereby improving user convenience.

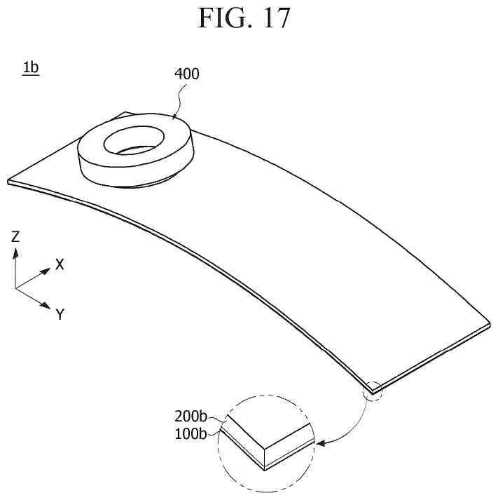

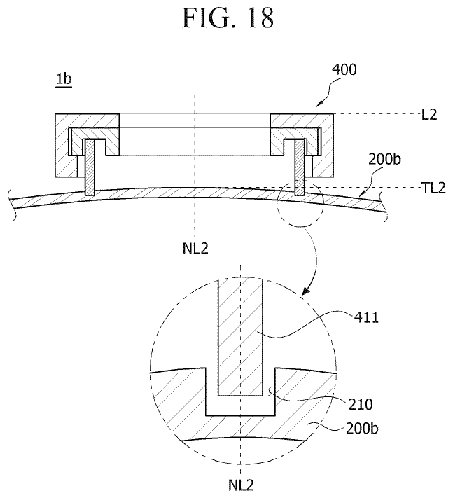

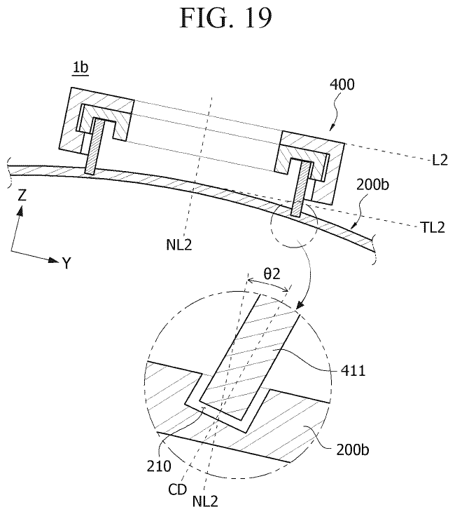

FIG. 17 is a perspective view illustrating a display device according to one or more embodiments of the present disclosure. FIG. 18 is a cross-sectional view illustrating a display device according to one or more embodiments of the present disclosure, which may show an arrangement relationship between the knob and the cover, and the enlarged portion of FIG. 18 may be a conceptual view showing technical characteristics of a display device according to one or more embodiments of the present disclosure. FIG. 19 is a cross-sectional view illustrating a display device according to one or more embodiments of the present disclosure, which may show another arrangement relationship between the knob and the cover, and the enlarged portion of FIG. 19 may be a conceptual view showing technical characteristics of a display device according to one or more embodiments of the present disclosure. Herein, the convex type display device illustrated in FIG. 18 may be referred to as a display device according to a fourth embodiment of the present disclosure, and the convex type display device illustrated in FIG. 19 may be referred to as a display device according to a fifth embodiment of the present disclosure.

When comparing the display device 1 according to the first embodiment with the display device 1b according to the fourth and fifth embodiments with reference to FIGS. 1 and 17, the display device 1b according to the fourth and fifth embodiments differs from the display device 1 according to the first embodiment in that the cover 200b in the display device 1b according to the fourth and fifth embodiments includes a convex curved surface.

In addition, when comparing the display device 1b according to the fourth embodiment with the display device 1b according to the fifth embodiment, the display device 1b according to the fourth embodiment differs from the display device 1b according to the fifth embodiment in that the upper surface of the knob 400 in the display device 1b according to the fourth embodiment is disposed parallel to a tangent line passing through the curved surface of the cover 200b. Here, the tangent line passing through the curved surface of the cover 200b may be a tangent line at the center C of the groove 210.

Referring to FIGS. 17 to 19, the display device 1b according to one or more embodiments of the present disclosure may include a display panel 100b, a cover 200b including a convex curved surface disposed on the front surface of the display panel 100b and formed to have a predetermined curvature, an adhesive member 300 disposed in the groove 210 concavely formed in the front surface of the cover 200b, and a knob 400 coupled to the groove 210 through the adhesive member 300. In this case, the groove 210 may be formed in a ring shape having a predetermined depth. Further, the display device 1b according to another embodiment of the present disclosure may include a key groove 220, a key 430 formed to correspond to the key groove 220, centering ribs 440a and 440b, and the like.

The display panel 100b may include a curved surface corresponding to the curved surface of the cover 200b.

The display panel 100b may include a circuit layer 120 disposed on the panel substrate 110, a light-emitting element layer 130 disposed on the circuit layer 120, an encapsulation layer 140 disposed on the light-emitting element layer 130, and a touch sensor layer 150 formed on the encapsulation layer 140.

The cover 200b includes a convex curved surface formed to have a predetermined curvature, and the curved surface may be the front surface of the cover 200b. Accordingly, it may include an imaginary tangent line TL2 contacting the curved surface of the cover 200b.

Depending on the position where the convex type display device 1b is disposed in the vehicle, a difference may occur in the viewing angle of the user viewing the knob 400.

The user's convenience in recognizing the knob 400 may be improved by adjusting the arrangement of the groove 210 in consideration of the position where the convex type display device 1b is disposed.

Referring to FIG. 18, in the display device 1b according to the fourth embodiment, an imaginary straight line L2 passing through the upper surface of the knob 400 may be disposed in parallel with an imaginary tangent line TL2 contacting the curved surface of the cover 200b. Accordingly, the imaginary normal line NL2 perpendicular to the tangent line TL2 may be perpendicular to the imaginary straight line L2 passing through the upper surface of the knob 400. Here, the upper surface of the knob 400 may be the upper surface of the dial 420.

In this case, the coupling direction CD of the knob 400 of the display device 1b according to the fourth embodiment may be the same as the normal line NL2.

Referring to FIG. 19, in the display device 1b according to the fifth embodiment, the imaginary straight line L2 passing through the upper surface of the knob 400 may be disposed in non-parallel with the imaginary tangent line TL2 contacting the curved surface of the cover 200b. Accordingly, there is an intersection point at which the imaginary straight line L2 meets the imaginary tangent line TL2. And, the normal line NL2 perpendicular to the tangent line TL2 may be disposed to have a predetermined second inclination angle θ2 with respect to the coupling direction CD in which the support part 411 of the knob 400 is coupled to the groove 210. That is, since the groove 210 of the cover 200b is disposed to be inclined with respect to the normal line NL2, an acute included angle may be formed between the coupling direction CD of the knob 400 and the normal line NL2. Accordingly, the knob 400 may be coupled to the groove 210 formed to be inclined on the front surface of the cover 200b, thereby improving the user's convenience in recognizing the knob 400.

The curved display device described above may include a concave type display device and a convex type display device each having at least two curvatures.

By adjusting at least one of the depth of the groove and the length of the support part of the knob in consideration of the position of the knob disposed on the concave type or convex type display device, the display device according to the embodiment of the present disclosure may improve the user's convenience in recognizing the knob.

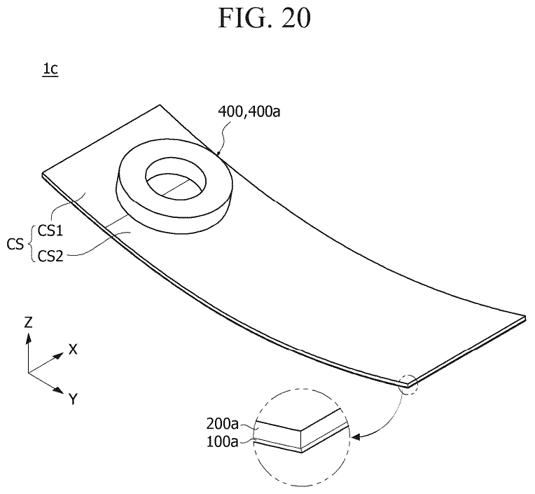

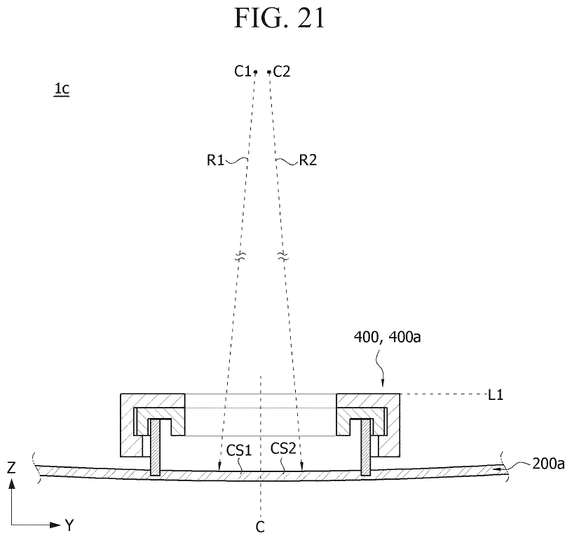

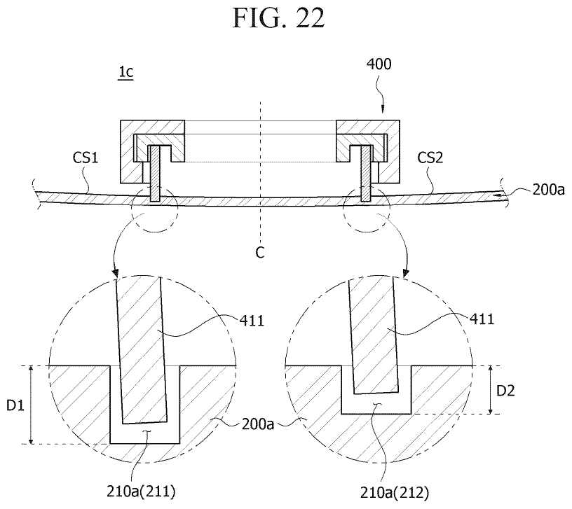

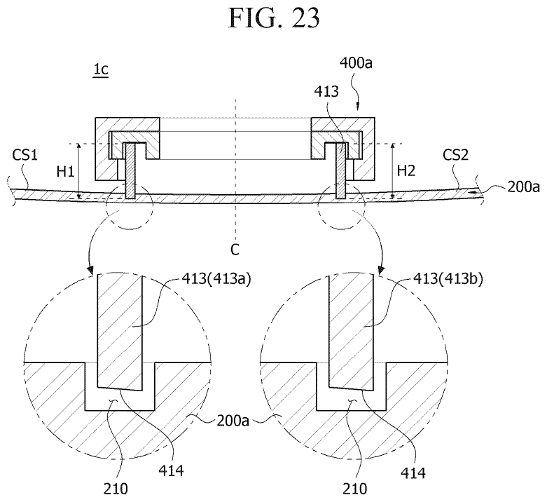

FIG. 20 is a perspective view illustrating a display device according to one or more embodiments of the present disclosure, and FIG. 21 is a view illustrating a cover having at least two curvatures in a display device according to one or more embodiments of the present disclosure. FIG. 22 is a cross-sectional view illustrating a display device according to one or more embodiments of the present disclosure, and may illustrate an arrangement relationship between the knob and the cover, and the enlarged portion of FIG. 22 may be a conceptual view illustrating technical features of the display device according to one or more embodiments of the present disclosure. FIG. 23 is a cross-sectional view illustrating a display device according to one or more embodiments of the present disclosure, and may show another arrangement relationship between the knob and the cover, and the enlarged portion of FIG. 23 may be a conceptual view illustrating technical features of the display device according to one or more embodiments of the present disclosure. Here, the concave type display device illustrated in FIG. 22 may be referred to as a display device according to a sixth embodiment of the present disclosure, and the concave type display device illustrated in FIG. 23 may be referred to as a display device according to a seventh embodiment of the present disclosure.

When comparing the display device 1a according to the second and third embodiments with the display device 1c according to the sixth and seventh embodiments with reference to FIG. 14 and FIGS. 20 to 23, the cover 200a of the display device 1c according to the sixth and seventh embodiments differs from that of the display device 1a according to the second and third embodiments in that it includes at least two concave curved surfaces CS1 and CS2 with different curvatures, and in that the depth of the groove 210a and/or the length of the support part 411a of the knob 400a are adjusted to correspond to the at least two concave curved surfaces CS1 and CS2.

Referring to FIGS. 20 and 21, the curved surface CS of the cover 200a may include a first curved surface CS1 and a second curved surface CS2 having different curvatures from each other. In addition, the first curved surface CS1 and the second curved surface CS2 may be disposed to overlap the knobs 400 and 400a. In this case, the imaginary boundary line positioned at the point where the first curved surface CS1 and the second curved surface CS2 meet may pass through the center of the groove 210a, but is not necessarily limited thereto. Here, the curvature 1/R1 of the first curved surface CS1 and the curvature 1/R2 of the second curved surface CS2 are different from each other. For example, the curvature 1/R1 of the first curved surface CS1 may be formed to be greater than the curvature 1/R2 of the second curved surface CS2. In addition, the curvature center C1 of the first curved surface CS1 and the curvature center C2 of the second curved surface CS2 are disposed to be closer to the cover 200a than to the display panel 100a.

Referring to FIGS. 20 to 23, a display device 1c according to one or more embodiments of the present disclosure may include a display panel 100a, a cover 200a disposed on the front surface of the display panel 100a and including a concave curved surface CS, an adhesive member 300 disposed in grooves 210 and 210a concavely formed on the front surface of the cover 200a, and knobs 400 and 400a coupled to grooves 210 and 210a through the adhesive member 300. In this case, the grooves 210 and 210a may be formed in a ring shape having a predetermined depth. Further, the display device 1c according to one or more embodiments of the present disclosure may include a key groove 220, a key 430 formed to correspond to the key groove 220, centering ribs 440a and 440b, and the like.

The display panel 100a may include a curved surface corresponding to the curved surface of the cover 200a.

The display panel 100a may include a circuit layer 120 disposed on the panel substrate 110, a light-emitting element layer 130 disposed on the circuit layer 120, an encapsulation layer 140 disposed on the light-emitting element layer 130, and a touch sensor layer 150 formed on the encapsulation layer 140.

The cover 200a includes a concave curved surface CS formed to have a predetermined curvature, and the curved surface CS may include a first curved surface CS1 and a second curved surface CS2 having different curvatures. In this case, the curved surface CS may be the front surface of the cover 200a.

By adjusting the depth of the groove 210a and/or the support part 411a in consideration of the position where the concave type display device 1c is disposed and at least two curved surfaces CS1 and CS2 with different curvatures, the convenience for the user recognizing the knob 400 and 400a may be improved.

Referring to FIG. 22, the display device 1c according to the sixth embodiment may include a display panel 100a, a cover 200a including at least two curved surfaces CS1 and CS2 disposed in front of the display panel 100a and having different curvatures, an adhesive member 300 disposed in a groove 210a concavely formed in front of the cover 200a, and a knob 400 coupled to the groove 210a through the adhesive member 300.

The groove 210a may be formed with different depths on one side and the other side. For example, the depth of the groove 210a may decrease from one side to the other side. Accordingly, since the width of the groove 210a is greater than the width of the support part 411, even when the length of the support part 411 is constant, the knob 400 may be obliquely disposed corresponding to the depth of the groove 210a.

When the curvature 1/R1 of the first curved surface CS1 is formed to be greater than the curvature 1/R2 of the second curved surface CS2, the first depth D1 in the first groove region 211 is formed to be greater than the second depth D2 in the second groove region 212, and the depth of the groove 210a may decrease from the first groove region 211 to the second groove region 212. Here, the first groove region 211 may represent a region having the deepest depth of the groove 210a, and the second groove region 212 may represent a region having the shallowest depth of the groove 210a.

Therefore, in the display device 1c according to the sixth embodiment, the angle of the knob 400 may be adjusted so that the upper surface of the knob 400 is well recognized by the user by adjusting the depth of the groove 210a. For example, by forming the depth of the groove 210a on the side of the curved surface having a larger curvature to be deeper than the depth of the groove 210a on the side of the curved surface having a smaller curvature in the curved surfaces CS1 and CS2 having at least two curvatures, the user's convenience in recognizing the knob 400 may be improved.

Referring to FIG. 23, the display device 1c according to the seventh embodiment may include a display panel 100a, a cover 200a including at least two curved surfaces CS1 and CS2 disposed in front of the display panel 100a and having different curvatures, an adhesive member 300 disposed in a groove 210 concavely formed in front of the cover 200a, and a knob 400a coupled to the groove 210 through the adhesive member 300.

The knob 400a may include a body 410 coupled to the groove 210 and a dial 420 rotatably disposed on the body 410. Further, the body 410 may include a support part 413 coupled to the groove 210 and a body part 412 disposed on the support part 413.

The support part 413 may be formed in a sleeve shape, a cylindrical shape, or a pipe shape having a predetermined length, and the length of the support part 413 may increase from one side to the other side. Accordingly, the lower surface 414 of the support part 413 may be formed as an inclined surface having a predetermined inclination.

The support part 413 may be formed with different lengths on one side and the other side. For example, the length of the support part 413 may increase from one side to the other side. When the curvature 1/R1 of the first curved surface CS1 is formed to be greater than the curvature 1/R2 of the second curved surface CS2, the first length H1 in the first support region 413a may be formed to be smaller than the second length H2 in the second support region 413b, and the length of the support part 413 may increase from the first support region 413a to the second support region 413b. Here, the first support region 413a may represent a region having the shortest length of the support part 413, and the second support region 413b may represent a region having the longest length of the support part 413.

Accordingly, the display device 1c according to the seventh embodiment may adjust the angle of the knob 400a so that the upper surface of the knob 400a is well recognized by the user by adjusting the length of the support part 413. For example, in the curved surfaces CS1 and CS2 having at least two curvatures, the length of the support part 413 on the curved surface side having a large curvature is formed to be shorter than the length of the support part 413 on the curved surface side having a small curvature, thereby improving the user's convenience in recognizing the knob 400a.

In the display device 1c according to still further another embodiment of the present disclosure, the display device 1c shown in FIG. 22 is an example of adjusting the depth of the groove 210a, and the display device 1c shown in FIG. 23 is an example of adjusting the length of the support part 413, but is not necessarily limited thereto. For example, both the depth of the groove 210a and the length of the support part 413 may be adjusted to correspond to at least two curved surfaces CS1 and CS2 having different curvatures.

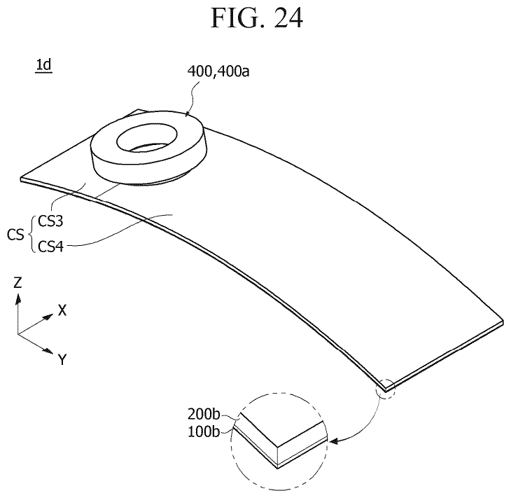

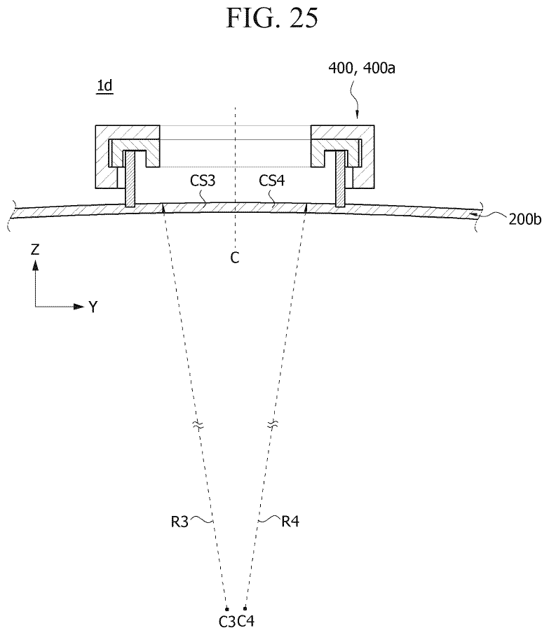

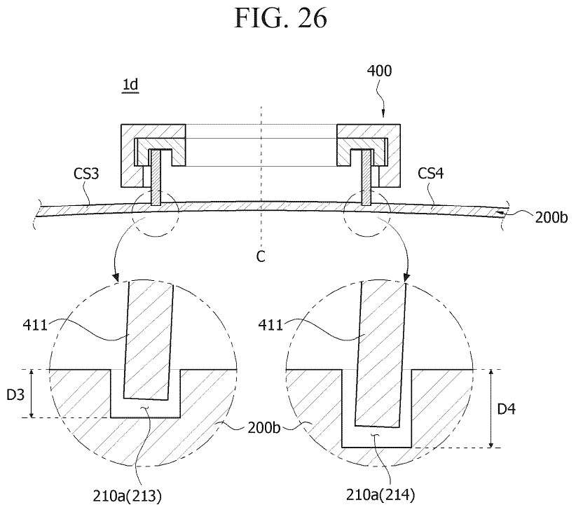

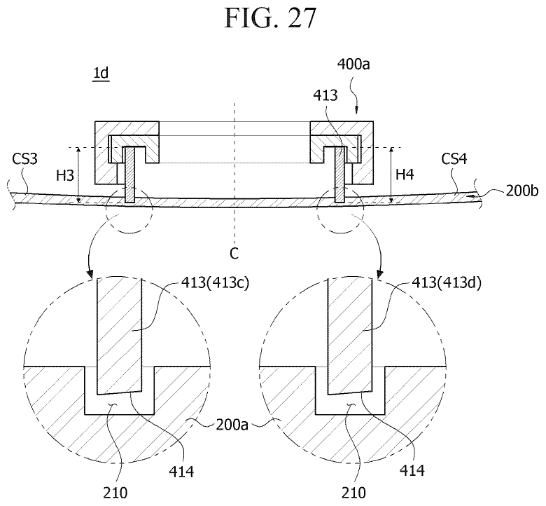

FIG. 24 is a perspective view illustrating a display device according to one or more embodiments of the present disclosure, and FIG. 25 is a view illustrating a cover having at least two curvatures in a display device according to one or more embodiments of the present disclosure. FIG. 26 is a cross-sectional view illustrating a display device according to one or more embodiments of the present disclosure, and may illustrate an arrangement relationship between a knob and a cover, and the enlarged portion of FIG. 26 may be a conceptual view illustrating technical features of the display device according to one or more embodiments of the present disclosure. FIG. 27 is a cross-sectional view illustrating a display device according to one or more embodiments of the present disclosure, and may illustrate another arrangement relationship between a knob and a cover, and the enlarged portion of FIG. 27 may be a conceptual view illustrating technical features of the display device according to one or more embodiments of the present disclosure. In this case, the convex type display device illustrated in FIG. 26 may be referred to as a display device according to an eighth embodiment of the present disclosure, and the convex type display device illustrated in FIG. 27 may be referred to as a display device according to a ninth embodiment of the present disclosure.

When comparing the display device 1b according to the fourth and fifth embodiments with the display device 1d according to the eighth and ninth embodiments with reference to FIG. 17 and FIGS. 24 to 27, the cover 200b of the display device 1d according to the eighth and ninth embodiments differs from that of the display device 1b according to the fourth and fifth embodiments in that it includes at least two convex curved surfaces CS3 and CS4 with different curvatures, and in that the depth of the groove 210a and/or the length of the support part 411a of the knob 400a are adjusted to correspond to the at least two convex curved surfaces CS3 and CS4.

Referring to FIGS. 24 and 25, the curved surface CS of the cover 200a may include a third curved surface CS3 and a fourth curved surface CS4 having different curvatures from each other. And, the third curved surface CS3 and the fourth curved surface CS4 may be disposed to overlap the knobs 400 and 400a. In this case, the imaginary boundary line positioned at the point where the third curved surface CS3 and the fourth curved surface CS4 meet may pass through the center of the groove 210a, but is not necessarily limited thereto. In this case, the curvature 1/R3 of the third curved surface CS3 is different from the curvature 1/R4 of the fourth curved surface CS4. For example, the curvature 1/R3 of the third curved surface CS3 may be formed to be greater than the curvature 1/R4 of the fourth curved surface CS4. And, the curvature center C3 of the third curved surface CS3 and the curvature center C4 of the fourth curved surface CS4 are disposed to be closer to the display panel 100b than to the cover 200b.

Referring to FIGS. 24 to 27, a display device 1d according to one or more embodiments of the present disclosure may include a display panel 100b, a cover 200b disposed on a front surface of the display panel 100b and including a convex curved surface CS, an adhesive member 300 disposed in grooves 210 and 210a concavely formed on a front surface of the cover 200b, and knobs 400 and 400a coupled to grooves 210 and 210a through the adhesive member 300. In this case, the grooves 210 and 210a may be formed in a ring shape having a predetermined depth. Further, a display device 1d according to one or more embodiments of the present disclosure may include a key groove 220, a key 430 formed to correspond to the key groove 220, and centering ribs 440a and 440b.

The display panel 100b may include a curved surface corresponding to the curved surface of the cover 200b.

The display panel 100b may include a circuit layer 120 disposed on the panel substrate 110, a light-emitting element layer 130 disposed on the circuit layer 120, an encapsulation layer 140 disposed on the light-emitting element layer 130, and a touch sensor layer 150 formed on the encapsulation layer 140.

The cover 200b includes a convex curved surface CS formed to have a predetermined curvature, and the curved surface CS may include a third curved surface CS3 and a fourth curved surface CS4 having different curvatures. In this case, the curved surface CS may be a front surface of the cover 200b.

By adjusting the depth of the groove 210a and/or the support part 411a in consideration of the location where the convex type display device 1d is disposed and the at least two curved surfaces CS3, CS4 having different curvatures, the user's convenience in recognizing the knobs 400 and 400a may be improved.

Referring to FIG. 26, the display device 1d according to the eighth embodiment may include a display panel 100b, a cover 200b including at least two curved surfaces CS3 and CS4 disposed in front of the display panel 100b and having different curvatures, an adhesive member 300 disposed in a groove 210a concavely formed in front of the cover 200b, and a knob 400 coupled to the groove 210a through the adhesive member 300.

The groove 210a may be formed to have different depths on one side and the other side. For example, the depth of the groove 210a may increase from one side to the other side. Accordingly, since the width of the groove 210a is greater than the width of the support part 411, even when the length of the support part 411 is constant, the knob 400 may be obliquely disposed to correspond to the depth of the groove 210a.

When the curvature 1/R3 of the third curved surface CS3 is formed to be larger than the curvature 1/R4 of the fourth curved surface CS4, the third depth D3 in the third groove region 213 may be formed to be smaller than the fourth depth D4 in the fourth groove region 214, and the depth of the groove 210a may increase from the third groove region 213 to the fourth groove region 214. In this case, the third groove region 213 may represent a region having the shallowest depth of the groove 210a, and the fourth groove region 214 may represent a region having the deepest depth of the groove 210a.

Therefore, in the display device 1d according to the eighth embodiment, the angle of the knob 400 may be adjusted by adjusting the depth of the groove 210a so that the top surface of the knob 400 is well recognized by the user. For example, for the curved surface CS3 and CS4 having at least two curvatures, the depth of the groove 210a on the curved surface side having a larger curvature is formed to be shallower than the depth of the groove 210a on the curved surface side having a smaller curvature, thereby improving the user's convenience in recognizing the knob 400.

Referring to FIG. 27, the display device 1d according to the ninth embodiment may include a display panel 100b, a cover 200b including at least two curved surfaces CS3 and CS4 disposed in front of the display panel 100b and having different curvatures, an adhesive member 300 disposed in a groove 210 concavely formed in front of the cover 200b, and a knob 400a coupled to the groove 210 through the adhesive member 300.

The knob 400a may include a body 410 coupled to the groove 210 and a dial 420 rotatably disposed on the body 410. In addition, the body 410 may include a support part 413 coupled to the groove 210 and a body part 412 disposed on the support part 413.

The support part 413 may be formed in a sleeve shape, a cylindrical shape, or a pipe shape having a predetermined length, and the length of the support part 413 may decrease from one side to the other side. Accordingly, the lower surface 414 of the support part 413 may be formed as an inclined surface having a predetermined inclination.

The support part 413 may be formed to have different lengths on one side and the other side thereof. For example, the length of the support part 413 may decrease from one side to the other side. When the curvature 1/R3 of the third curved surface CS3 is formed to be greater than the curvature 1/R4 of the fourth curved surface CS4, the third length H3 in the third support region 413c is formed to be larger than the fourth length H4 in the fourth support region 413d, and the length of the support part 413 may decrease from the third support region 413c to the fourth support region 413d. In this case, the third support region 413c may represent a region having the longest length of the support part 413, and the fourth support region 413d may represent a region having the shortest length of the support part 413.

Therefore, in the display device 1d according to the ninth embodiment, the angle of the knob 400a may be adjusted by adjusting the length of the support part 413 so that the top surface of the knob 400a is well recognized by the user. For example, by forming the length of the support part 413 on the side of the curved surface having a larger curvature to be longer than the length of the support part 413 on the side of the curved surface having a smaller curvature in the curved surfaces CS3, CS4 having at least two curvatures, the user's convenience in recognizing the knob 400a may be improved.

In the display device 1d according to one or more embodiments of the present disclosure, the display device 1d shown in FIG. 26 is an example of adjusting the depth of the groove 210a, and the display device 1d shown in FIG. 27 is an example of adjusting the length of the support part 413, but is not necessarily limited thereto. For example, both the depth of the groove 210a and the length of the support part 413 may be adjusted to correspond to at least two curved surfaces CS3 and CS4 having different curvatures.

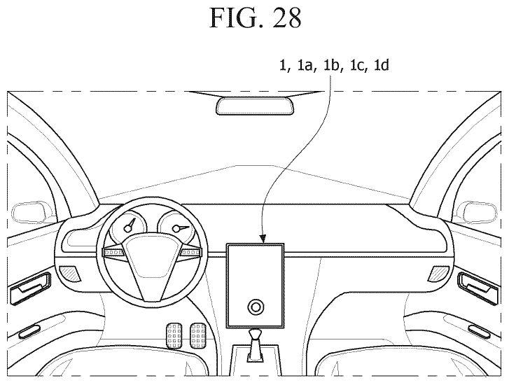

FIG. 28 is a view illustrating an example of use of a display device, wherein the display device is disposed inside the vehicle according to one or more embodiments of the present disclosure.

As shown in FIG. 28, the display devices 1, 1a, 1b, 1c, and 1d according to one or more embodiments of the present disclosure may each be disposed on at least a portion of a dash board of the vehicle. Here, the dashboard of the vehicle may refer to some components of the vehicle disposed in front of a front seat (e.g., a driver's seat, a passenger seat) of the vehicle.

In addition, an input configuration for operating various functions (for example, an air conditioner, an audio system, and a navigation system) provided to the vehicle may be disposed on the dashboard of the vehicle.

The display devices 1, 1a, 1b, 1c, and 1d may each be disposed on a dashboard of the vehicle to perform an operation as an input part for operating at least a portion of various functions of the vehicle. In addition, the display devices 1, 1a, 1b, 1c, and 1d may provide various information related to the vehicle, for example, driving information (e.g., current speed of the vehicle, remaining fuel amount, driving distance), and information on components of the vehicle (e.g., damage to a vehicle tire).

Further, the display devices 1, 1a, 1b, 1c, and 1d may each be disposed between the driver's seat and the passenger seat disposed in the front seat of the vehicle. And, the user of the display devices 1, 1a, 1b, 1c, and 1d may include the driver of the vehicle and the passenger who rides in the passenger seat, but is not necessarily limited thereto. For example, the display devices 1, 1a, 1b, 1c, and 1d may be provided for a passenger in the rear seat.

The display devices 1, 1a, 1b, 1c, and 1d shown in FIG. 28 may each be partially illustrated. The display devices 1, 1a, 1b, 1c, and 1d shown in FIG. 28 may each represent a display panel in which knobs are mounted among various configurations included in the display device 1. Configurations of each of the display devices 1, 1a, 1b, 1c, and 1d other than those shown in FIG. 28 may be mounted inside the vehicle.

A display device mounted on a vehicle is one example for describing the present disclosure, and embodiments of the present disclosure is not limited thereto. For example, the display device according to one or more embodiments of the present disclosure may be applied to a mobile device, a medical device, vehicle navigation device, a vehicle display device, a wall paper device, a home appliance, and the like. And, the display device of the present disclosure may be applied to an organic light-emitting lighting device or an inorganic light-emitting lighting device.

The embodiments of the present disclosure described above will be briefly described as follows.

A display device according to one or more embodiments of the present disclosure includes: a display panel; a cover disposed on the front of the display panel; an adhesive member disposed in a groove concavely formed on the front surface of the cover; and a knob coupled to the groove through the adhesive member, wherein the groove is formed to have a ring shape.

In the display device according to one or more embodiments of the present disclosure, the knob may include a body coupled to the groove and a dial rotatably disposed on the body, and the body may include a support part coupled to the groove and a body part disposed on the support part.

In the display device according to one or more embodiments of the present disclosure, the cover may further include a key groove extending in the radial direction from the groove, and the knob may further include a key protruding from the support part to correspond to the key groove.

In the display device according to one or more embodiments of the present disclosure, the knob may further includes at least two centering ribs formed to protrude from the outer circumferential surface of the support part, and the centering rib may be in point contact or line contact with the inner side surface of the groove.

In the display device according to one or more embodiments of the present disclosure, the cover may be formed of a glass material, the display panel may include a substrate, a circuit layer disposed on the substrate to drive pixels, a light-emitting element layer disposed on the circuit layer, an encapsulation layer configured to cover the circuit layer and the light-emitting element layer, and a touch sensor layer disposed on the encapsulation layer, and the touch sensor layer may include an insulating film of an organic material which contacts the cover.

A display device according to one or more embodiments of the present disclosure includes: a display panel; a cover disposed on the front of the display panel; an adhesive member disposed in a groove concavely formed on the front surface of the cover; and a knob coupled to the groove through the adhesive member, wherein the groove may have a ring shape, the cover may include a curved surface formed to have a predetermined curvature, and the knob may be obliquely arranged to have a predetermined angle with the normal line of the curved surface.

In the display device according to one or more embodiments of the present disclosure, the knob may include a body coupled to the groove and a dial rotatably disposed on the body, the body may include a support part coupled to the groove and a body part disposed on the support part, and the length of the support part may increases from one side to the other side. In the display device according to one or more embodiments of the present disclosure,

the knob may include a body coupled to the groove and a dial rotatably disposed on the body, the body may include a support part coupled to the groove and a body part disposed on the support part, and the depth of the groove may decreases from one side to the other side.

In the display device according to one or more embodiments of the present disclosure, the groove may be formed to be inclined on the front surface of the cover.

In the display device according to one or more embodiments of the present disclosure, the curved surface may include a first curved surface and a second curved surface having different curvatures, and the knob may be disposed to overlap the first curved surface and the second curved surface.

In the display device according to one or more embodiments of the present disclosure, the curved surface formed in a concave type may include a first curved surface and a second curved surface having different curvatures, the groove may include a first groove region having a first depth and a second groove region having a second depth, the first groove region may be disposed on the first curved surface, the second groove region may be disposed on the second curved surface, and the first depth and the second depth may be different from each other.

In the display device according to one or more embodiments of the present disclosure, the knob may include a support part coupled to the groove, a body including a body part disposed on the support part, and a dial rotatably disposed on the body part, the curved surface formed in a concave type may include a first curved surface and a second curved surface having different curvatures, a first support region of the support part may be disposed on the first curved surface, a second support region of the support part may be disposed on the second curved surface, and length of the first support region and a length of the second support region may be different from each other.

In the display device according to one or more embodiments of the present disclosure, the curved surface formed in a convex type may include a third curved surface and a fourth curved surface having different curvatures, the groove may include a third groove region having a third depth and a fourth groove region having a fourth depth, the third groove region may be disposed on the third curved surface, the fourth groove region may be disposed on the fourth curved surface, and the third depth and the fourth depth may be different from each other.

In the display device according to one or more embodiments of the present disclosure, the knob may include a support part coupled to the groove, a body including a body part disposed on the support part, and a dial rotatably disposed on the body part, the curved surface formed in a convex type may include a third curved surface and a fourth curved surface having different curvatures, a third support region of the support part may be disposed on the third curved surface, a fourth support region of the support part may be disposed on the fourth curved surface, and a length of the third support region and a length of the fourth support region may be different from each other.

In the display device according to one or more embodiments of the present disclosure, the knob may include a body coupled to the groove and a dial rotatably disposed on the body, and the body may include a support part coupled to the groove and a body part disposed on the support part.

In the display device according to one or more embodiments of the present disclosure, the cover may further include a key groove extending in the radial direction from the groove, and the knob may further include a key protruding from the support part to correspond to the key groove.

In the display device according to one or more embodiments of the present disclosure, the knob may further include at least two centering ribs formed to protrude from the outer circumferential surface of the support part, and, the centering rib may be in point contact or line contact with the inner side surface of the groove.

In the display device according to one or more embodiments of the present disclosure, the cover may be formed of a glass material, the display panel may include a substrate, a circuit layer disposed on the substrate to drive pixels, a light-emitting element layer disposed on the circuit layer, an encapsulation layer configured to cover the circuit layer and the light-emitting element layer, and a touch sensor layer disposed on the encapsulation layer, and the touch sensor layer may include an insulating film of an organic material which contacts the cover.

The objects to be achieved by the present disclosure, the means for achieving the objects, and effects of the present disclosure described above do not specify essential features of the claims, and thus, the scope of the claims is not limited to the disclosure of the present disclosure.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure.

### DESCRIPTION OF REFERENCE NUMERALS

| | |
|---|---|
| 1, 1a, 1b, 1c, 1d: Display devices | 100, 100a, 100b: Display panels |
| 110: Panel substrate | 120: Circuit layer |
| 130: Light-emitting element layer | |
| 140: Encapsulation layer | 150: Touch sensor layer |
| 152: Insulating film | 200, 200a, 200b: Covers |
| 210, 210a: Grooves | 220: Key groove |
| 300: Adhesive member | 400, 400a: Knobs |
| 410: Body | 411, 413: Support parts |
| 420: Dial | 430: Key |
| 440a, 440b: Centering ribs | |

What is claimed is:

1. A display device, comprising:
a display panel;
a cover on a front surface of the display panel;
an adhesive member in a groove, the groove is in a concave form on a front surface of the cover and has a ring shape; and
a knob coupled to the groove through the adhesive member.

2. The display device of claim 1, wherein:
the knob includes a body that is coupled to the groove and a rotatable dial on the body, and
the body includes a support part that is coupled to the groove and a body part on the support part.

3. The display device of claim 2, wherein:
the cover further includes a key groove that extends from the groove in a radial direction, and
the knob further includes a key that protrudes from the support part, the key corresponds to the key groove.

4. The display device of claim 2, wherein:
the knob further includes at least two centering ribs that protrude from an outer circumferential surface of the support part, and
a centering rib of the at least two centering ribs is in a point contact with an inner side surface of the groove or the centering rib is in a line contact with the inner side surface of the groove.

5. The display device of claim 2, wherein:
a lower side surface of the support part includes an inclined surface of a predetermined inclination.

6. The display device of claim 1, wherein:
the cover includes a glass material,
the display panel includes a substrate, a circuit layer on the substrate for driving pixels of the display panel, a light-emitting element layer on the circuit layer, an encapsulation layer on the circuit layer and the light-emitting element layer, and a touch sensor layer on the encapsulation layer, and
the touch sensor layer includes an insulating film of an organic material, the insulating film in contact with the cover.

7. A display device, comprising:
a display panel;
a cover on a front surface of the display panel, the cover including a curved surface of a predetermined curvature;
an adhesive member in a concave groove on a front surface of the cover, the concave groove having a ring shape; and
a knob coupled to the concave groove through the adhesive member, the knob obliquely arranged and having a predetermined angle to a normal line of the curved surface.

8. The display device of claim 7, wherein:
the knob includes a body that is coupled to the concave groove and a rotatable dial on the body,
the body includes a support part that is coupled to the concave groove and a body part on the support part, and
a first length of a first side of the support part is smaller than a second length of a second side of the support part.

9. The display device of claim 7, wherein:
the knob includes a body that is coupled to the concave groove and a rotatable dial on the body,
the body includes a support part that is coupled to the concave groove and a body part on the support part, and
a first depth of a first side of the concave groove is greater than a second depth of a second side of the concave groove.

10. The display device of claim 7, wherein the concave groove is inclined on the front surface of the cover.

11. The display device of claim 7, wherein:
the curved surface includes a first curved surface having a first curvature and a second curved surface having a second curvature that is different from the first curvature, and
the knob overlaps the first curved surface and the second curved surface.

12. The display device of claim 7, wherein:
the curved surface is of a concave type and includes a first curved surface having a first curvature and a second curved surface having a second curvature that is different from the first curvature, and
the concave groove includes a first groove region having a first depth and a second groove region having a second depth that is different from the first depth, the first groove region is on the first curved surface, and the second groove region is on the second curved surface.

13. The display device of claim 7, wherein:
the knob includes a body including a support part that is coupled to the concave groove and a body part on the support part, and a rotatable dial on the body part,
the curved surface is of a concave type and includes a first curved surface having a first curvature and a second curved surface having a second curvature that is different from the first curvature,
a first support region of the support part is on the first curved surface, the first support region having a first length, and
a second support region of the support part is on the second curved surface, the second support region having a second length that is different from the first length.

14. The display device of claim 7, wherein:
the curved surface is of a convex type and includes a first curved surface having a first curvature and a second curved surface having a second curvature that is different from the first curvature, and
the concave groove includes a first groove region having a first depth and a second groove region having a second depth that is different from the first depth, the first groove region is on the first curved surface, and the second groove region is on the second curved surface.

15. The display device of claim 7, wherein:
the knob includes a body including a support part that is coupled to the concave groove and a body part on the support part, and a rotatable dial on the body part,
the curved surface is of a convex type and includes a first curved surface having a first curvature and a second curved surface having a second curvature that is different from the first curvature,
a first support region of the support part is on the first curved surface, the first support region having a first length, and
a second support region of the support part is on the second curved surface, the second support region having a second length that is different from the first length.

16. The display device of claim 7, wherein:
the knob includes a body that is coupled to the concave groove and a rotatable dial on the body, and
the body includes a support part that is coupled to the concave groove and a body part on the support part.

17. The display device of claim 16, wherein:
the cover further includes a key groove that extends from the concave groove in a radial direction, and
the knob further includes a key that protrudes from the support part, the key corresponds to the key groove.

18. The display device of claim 16, wherein:
the knob further includes at least two centering ribs that protrude from an outer circumferential surface of the support part, and
a centering rib of the at least two centering ribs is in a point contact with an inner side surface of the concave groove or the centering rib is in a line contact with the inner side surface of the concave groove.

19. The display device of claim 7, wherein:
the cover includes a glass material,
the display panel includes a substrate, a circuit layer on the substrate for driving pixels of the display panel, a light-emitting element layer on the circuit layer, an encapsulation layer on the circuit layer and the light-emitting element layer, and a touch sensor layer on the encapsulation layer, and
the touch sensor layer includes an insulating film of an organic material, the insulating film in contact with the cover.

20. A display device, comprising:
a display panel;
a cover on a front surface of the display panel, the cover including a curved surface of a predetermined curvature;
an adhesive member in a concave groove and on a front surface of the cover, concave groove having a ring shape; and
a knob coupled to the concave groove through the adhesive member,
wherein a coupling direction of the knob is a same as or parallel to a normal line of the curved surface.
